(19) United States
(12) Patent Application Publication
(10) Pub. No.: US 2012/0309187 A1
(43) Pub. Date: Dec. 6, 2012

(54) Conformal Coining of Solder Joints in Electronic Packages

(75) Inventors: Sri M. Sri-Jayantha, Ossining, NY (US); Vijayeshwar D. Khanna, Millwood, NY (US)

(73) Assignee: INTERNATIONAL BUSINESS MACHINES CORPORATION, Armonk, NY (US)

(21) Appl. No.: 13/194,902

(22) Filed: Jul. 29, 2011

Related U.S. Application Data
(60) Provisional application No. 61/491,280, filed on May 30, 2011.

(51) Int. Cl. H01L 21/60

(52) U.S. Cl. 438/613; 257/E21.508

(57) ABSTRACT

Thermal deformation of a substrate and the substrate's warp at room temperature are used to determine the expected profile of the substrate at reflow. A contact surface profile of a coining pressure plate is selected based on the expected substrate profile. A solder surface is shaped on the substrate or a die to be joined to the substrate by the coining pressure plate, thereby facilitating the chip-joining process.

### CROSS-REFERENCE TO RELATED APPLICATION

This patent application claims the benefit of U.S. Provisional Patent Application Ser. No. 61/491,280 filed on May 30, 2011, and entitled “Conformal Coining of Solder Joints in Electronic Packages.” The disclosure of the aforementioned Provisional Patent Application Ser. No. 61/491,280 is expressly incorporated herein by reference in its entirety for all purposes.

### FIELD OF THE INVENTION

The present invention relates to the physical sciences, and, more particularly, to joining elements such as silicon dies and organic substrates using solder joints.

### BACKGROUND OF THE INVENTION

A silicon die and an organic substrate are joined at a reflow temperature associated with the melting temperature of the solder material used to effect joining of such elements. This temperature is about 240 degrees Centigrade for certain lead-free solders. The die has a multitude of solder bumps that are pre-formed on it, and are called C4's (Controlled Collapse Chip Connection). The substrate has copper pads on which solder material (about 25% by volume of the corresponding C4) is deposited through a screen printing process. The two components are brought together and held in place by a solder-flux material that helps to keep the solder surfaces clean to facilitate chip joining.

FIGS. 1a & 1b show the two components, silicon die 20 and a substrate 22 with C4's 24 and solder pads 26, respectively. FIG. 1a illustrates the location of the pads that are known to shift radially due to CTE (coefficient of thermal expansion) driven expansion process as temperature rises from room temperature to reflow temperature. FIG. 1b captures the radial shift as well as a z-gap component that occurs due to the deformation of the substrate 22 at reflow. The substrate 22 is shown schematically as a uniform object but may in fact be a laminate comprised of copper and polymer based materials. A typical laminate may have a relatively rigid core about 400 μm thick, usually comprised of fiberglass reinforced epoxy matrix at its center. It may have two to seven layers of copper planes on each side of the core about 15 μm thick separated by 35 μm thick layers of dielectric material made of polymer. In order to achieve high probability for the C4 and the solder 28 on the substrate pads to join, the physical gap between the surfaces must be kept below a threshold value. The radial shift can be precompensated by appropriate design of the pads so that the pads will be directly under the C4's for best joining condition.

Due to uncertain warp characteristics observed in organic substrates. z-gap control has emerged as a major challenge in the manufacturing of electronic packages. The warp of the laminate area under the chip foot print where the C4 array is located, referred to as flip chip attachment area (FCA), is critical to a successful reflow operation.

### SUMMARY OF THE INVENTION

Principles of the invention provide a coining process that facilitates the optimization of a C4-to-pad geometric profile to enhance the chip-joining process. The invention can be further refined to accommodate the stress relaxation observed in more complex substrates.

In one aspect, an exemplary method includes the steps of providing an organic substrate including a plurality of solder bumps, obtaining an expected profile of the organic substrate at reflow, selecting a contact surface profile for a contact surface of a coining pressure plate based on the expected profile of the organic substrate, and deforming the solder bumps by applying pressure to the solder bumps with the contact surface of the coining pressure plate, thereby forming a substrate solder surface having a profile corresponding to the contact surface profile of the coining pressure plate. The expected profile can be the expected profile of the particular organic substrate or a mean value of a population of similar substrates.

In another aspect, an exemplary method includes providing an organic substrate including a chip site comprising a plurality of first solder bumps, providing a die including a plurality of second solder bumps arranged for forming solder joints with the first solder bumps, and obtaining an expected profile of the chip site of the organic substrate at reflow. A desired solder surface profile for one of the pluralities of first and second solder bumps is determined based on the expected profile of the chip site of the organic substrate at reflow. The desired solder surface profile on the one of the pluralities of first and second solder bumps is provided by applying pressure to the one of the pluralities of first and second solder bumps with a coining plate. The contact surface of the coining plate may be selected to provide the desired solder surface profile. Alternatively, the organic substrate may be positioned on a surface having a profile that is selected based on the expected profile and coined with a plate having a planar surface.

A further exemplary embodiment of the invention provides a method that comprises determining whether an expected profile of a chip site on an organic substrate comprising solder bumps is convex at a reflow temperature of the solder bumps and coining the solder bumps with a coining pressure plate having a convex surface if the expected profile of the chip site is convex.

A computer program product is provided in accordance with a further aspect of the invention for selecting a coining profile for an organic substrate including a plurality of solder bumps on the substrate. A computer readable storage medium is provided having computer readable program code embodied therewith, the computer readable program code comprising computer readable program code containing program instructions, wherein execution of the instructions by one or more processors causes the one or more processors to carry out the steps of obtaining thermal warp information relating to the profile of an organic substrate including a plurality of solder bumps at a reflow temperature of the solder bumps, determining an expected profile of the organic substrate at reflow from the thermal warp information, and sending information relating to a coining profile to be chosen for the organic substrate based on the expected profile.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor, by sending appropriate data or commands to cause or aid the action to be performed. For the avoidance of doubt, where an actor facilitates an action by other than performing the action, the action is nevertheless performed by some entity or combination of entities.

One or more embodiments of the invention or elements thereof can be implemented in the form of a computer program product including a tangible computer readable recordable storage medium with computer usable program code for performing the method steps indicated. Furthermore, one or more embodiments of the invention or elements thereof can be implemented in the form of a system (or apparatus) including a memory, and at least one processor that is coupled to the memory and operative to perform exemplary method steps. Yet further, in another aspect, one or more embodiments of the invention or elements thereof can be implemented in the form of means for carrying out one or more of the method steps described herein; the means can include (i) hardware module(s), (ii) software module(s), or (iii) a combination of hardware and software modules; any of (i)-(iii) implement the specific techniques set forth herein, and the software modules are stored in a tangible computer-readable recordable storage medium (or multiple such media).

Techniques of the present invention can provide substantially beneficial technical effects. For example, one or more embodiments may provide one or more of the following advantages:
Increasing the probability that solder connections will be effectively formed at reflow:
Ensuring a flat or concave solder surface at reflow where such surfaces are necessary or desired;
Effectively processing substrates exhibiting different warp characteristics;
Using real-time warp measurement to improve a C4 joining process while accounting for creep relaxation

These and other features and advantages of the present invention will become apparent from the following detailed description of illustrative embodiments thereof, which is to be read in connection with the accompanying drawings.

### BRIEF DESCRIPTION OF THE DRAWINGS

FIG. 1a shows a silicon die and organic substrate, the die including solder bumps for controlled collapse chip connection (C4) with the substrate:

FIG. 1b is an enlarged view showing a gap between a solder bump on the die and a smaller solder bump on the substrate;

FIG. 2a is a surface profile of a substrate at reflow temperature;

FIG. 2b is a surface profile of the chip site of the substrate shown in FIG. 2a:

FIG. 3a is a chart showing reflow warp along a diagonal section of a first substrate;

FIG. 3b is a chart showing reflow warp along a diagonal section of a second substrate;

FIG. 3c is a schematic illustration of a substrate including a diagonal along which the profiles shown in FIGS. 3a and 3b are obtained;

FIG. 4 schematically illustrates various warp conditions for various substrates;

FIG. 5 is a graphical illustration showing thermal warp of a substrate at various temperatures;

FIG. 6a shows a first group of layers of a substrate;

FIG. 6b is a graph showing the stress and creep-strain of the substrate of FIG. 6a;

FIG. 6c shows a second group of layers of a substrate;

FIG. 6d is a graph showing the stress and creep-strain of the substrate of FIG. 6c;

FIG. 7a is an enlarged schematic illustration of a portion of the substrate of FIG. 3b showing warping of the substrate over time;

FIG. 7b is a graph illustrating creep strain and stress of the substrate of FIG. 3b as a function of time;

FIG. 7c is a schematic illustration of a spring damper model for detecting elastic and creep strain in a layer of the substrate of FIG. 3b;

FIG. 8a is an enlarged schematic illustration of a portion of the substrate of FIG. 3b in association with the spring damper model;

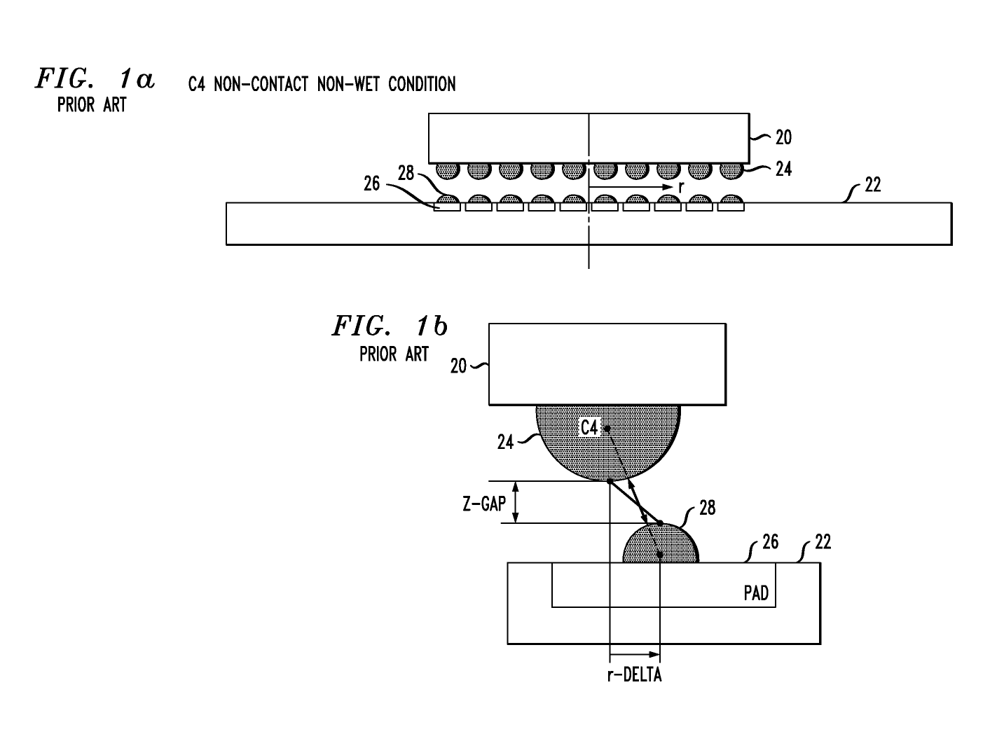

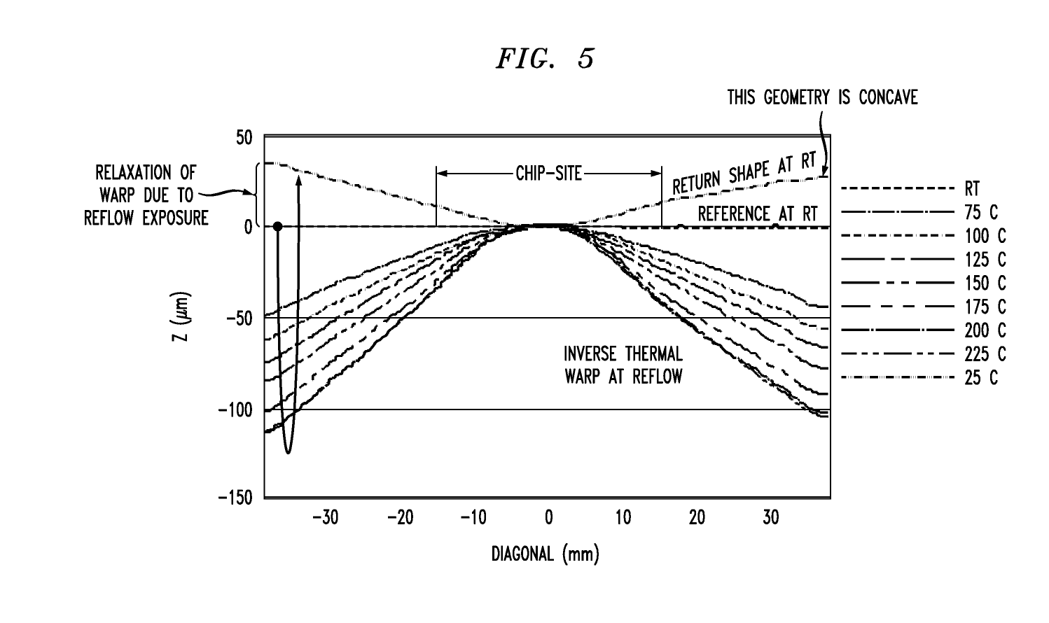

FIG. 5b is an enlarged schematic illustration thereof showing changes in the shape of the substrate during reflow;

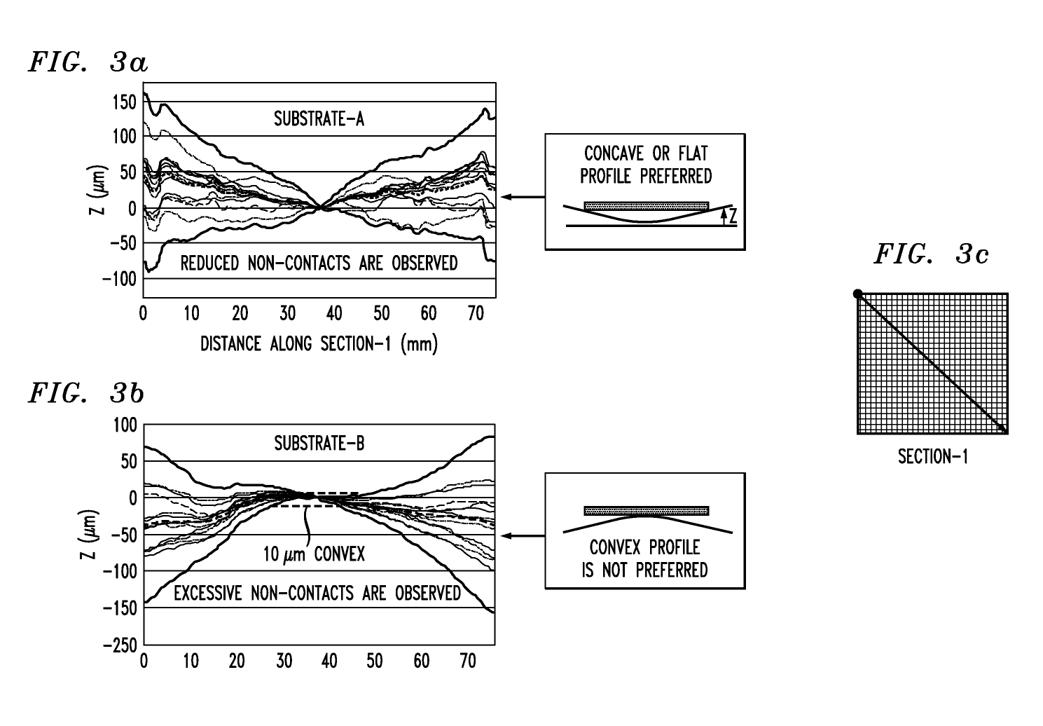

FIG. 9 is a schematic illustration of the substrate of FIG. 3b as its shape changes over time and due to thermal changes;

FIG. 10a schematically illustrates a conventional coining process followed by reflow;

FIG. 10b schematically illustrates a process in accordance with an exemplary embodiment of the invention wherein the coining profile is adapted to address expected changes in substrate shape from room temperature to reflow;

FIG. 11a schematically illustrates the reflow shape deficiency using conventional coining;

FIG. 11b schematically illustrates the modification of a conventional coining profile to address the reflow shape deficiency;

FIG. 12a schematically illustrates three possible substrate configurations at room temperature;

FIG. 12b schematically illustrates the thermal warp of a substrate;

FIG. 12c schematically illustrates three possible substrate configurations during reflow;

FIG. 13 is a flow chart showing the processing of a substrate wherein a coining profile is selected depending on the expected substrate configuration at reflow;

FIG. 14 is a schematic illustration of the steps employed for selecting an appropriate coining profile;

FIG. 15 shows the computation of the z-gap between the solder balls of the die and the substrate:

FIG. 16 schematically illustrates two procedures for performing a conformal coining process, and

FIG. 17 depicts a computer system that may be useful in implementing one or more aspects and/or elements of the invention.

### DETAILED DESCRIPTION OF PREFERRED EMBODIMENTS

Due to uncertain warp characteristics observed in organic substrates, z-gap control has emerged as a major challenge in the manufacturing of electronic packages. The invention addresses this problem by providing a coining process that provides a C4-to-pad geometric profile that enhances the chip-joining process. One or more embodiments of the invention are further directed to accommodating the stress relaxation observed in more complex substrates.

Conventional coining of a substrate strives to make the top surface of the solder on the substrate pads as coplanar as possible at room temperature by applying pressure to the solder using a flat surface pressure plate. However, the geometry or the substrate continues to change with temperature, and at reflow there is no guarantee that the substrate will remain flat so that the coined solder bumps will in turn define a flat, coplanar surface for producing good C4 joints.

The thermal deformation of a substrate can be estimated using warp projection models or can be evaluated using a warp measurement tool. Using laminate design information, a computational model to estimate temperature dependent warp can be developed for the substrate. Publication Nos. US 2009/0313588 A1, US 2009/0310848 A 1, US 2009/0312960 A1, each of which is incorporated by reference herein, disclose various methods of characterizing thermomechanical properties of organic substrates that can be used for warp modeling. The circuit layer patterns embedded in the substrate 22, made of copper planes, vary from layer to layer and laminate to laminate. The computational model captures the effect of thermal expansion of the materials used to build a laminate on change in warp as a function of temperature. An absolute value of warp is, however, difficult to estimate due to manufacturing uncertainty. The model can therefore only estimate an expected change in warp (called thermal warp), but can not estimate the exact individual laminate warp due to statistical variation encountered in the process. However, a measurement of warp of an individual substrate at room temperature, for example, can greatly enhance the estimated absolute warp at any other higher temperature using a computational model based thermal warp. The measurement of warp at room temperature is much more easily achieved in a high speed manufacturing environment compared to a warp measurement made at a higher temperatures because a laminate needs to be heated in an enclosure prior to warp measurement. Several tools to measure laminate warp are commercially available. They either use stereo images using two cameras or use optical Moire fringes to estimate warp. A substrate's warp at room temperature can be measured in real time with relative ease, and with the knowledge of the “thermal warp” component, the expected profile of the substrate at reflow can be constructed before a coining operation is performed. While the expected profile of the entire substrate can be obtained, the expected profile of the chip site area of the substrate where the die will be joined is more important. The profile of the coining pressure plate can be adaptively modified based on at least the thermal deformation information, possibly supplemented by the warp information at room temperature. The substrate solder surface can be plastically deformed to generate either a flat or a concave profile at the refow temperature. Alternatively, the solder surface of the die to be joined to the substrate can be coined by a modified coining pressure plate. This process will be referred to as “conformal coining”. In many practical cases of a substrate, the coining operation should involve generating a concave profile of the pad-solder surface. This is generally the case because the top build-up layers of a laminate in the chip area tend to have copper layers with patterns instead of solid copper planes found in bottom build-up layers. Copper patterns are more prone to larger expansion than solid copper planes. This effect tends to cause a thermal warp component that drives a concave geometry to become less and less concave with increasing temperature.

New generations of substrate designs where copper patterns are heavily employed in the bottom layer may also benefit from conformal coining. Conventional substrate design has circuitry etched on the top side of the laminate in the FCA. The bottom side of the laminate is mostly copper. In some new generations of laminate design, there is no guarantee that the bottom side will continue to be mostly solid copper. Cases where the bottom side has more circuitry than the top could lead to a reversal of profile shapes. i.e., what used to be convex in conventional substrate designs could become concave in new generations of laminate designs. It will be appreciated that a coining profile can be selected to address solder joining problems that may be found in both conventional and other laminate designs.

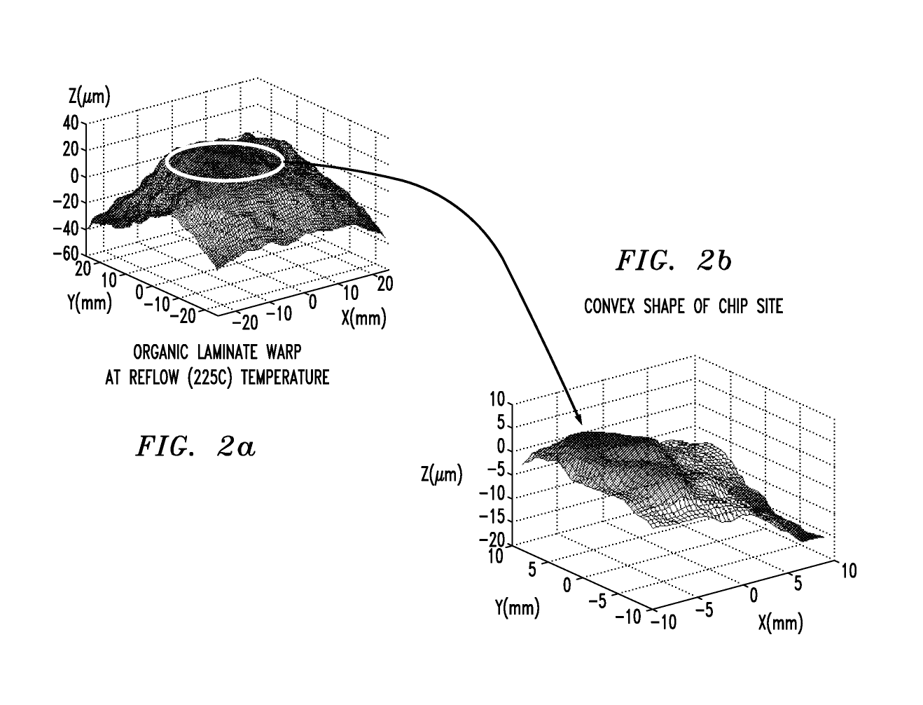

The “coining profile” is the profile that is used on the pressure plate. When the “coining profile” of the pressure plate is transferred through a perfect coining operation, the solder surface takes the exact shape of the “coining profile”. This means that when the active surface of the pressure plate is convex, the imprint it would make on the solder surface is a replica of the surface but will be viewed as a concave surface (looking down on the solder bumps). The profile that is associated with substrate is the free shape of the substrate at any given temperature. This is relevant because during the application of pressure, the laminate more or less becomes perfectly flat and the pressure plate profile (“coining profile”) is transferred to the solder bump surfaces (while under pressure). Once the pressure is removed the solder surfaces will further deform from the pressure-plate imposed profile by the amount corresponding to the substrate profile. Thus the word “conformal” is used to cover a general concept where a coining profile based on the expected reflow profile of a substrate is selected to facilitate the effective joining of a substrate to another element such as a die comprising an integrated circuit. In accordance with certain aspects of the invention, the coining process initially involves identifying various warp components in a substrate. They can be temperature and time dependent as discussed below with reference to FIGS. 2-9. Measuring the surface profiles at reflow temperatures is one way of identifying such warp components. Such measurements can be used for selecting the profile of the coining pressure plate in the conformal coining process disclosed herein.

FIGS. 2a & 2b illustrate the measured surface profile of an organic substrate at reflow temperature. The reflow temperature depends on the melting point of the solder and in this exemplary example is 225° C. It can be observed that the profile under the chip foot print (chip site) is convex when viewed from top down. The chip joining process has been found to be more sensitive when the substrate profile is convex rather than concave at reflow. Ideally, a flat or planar profile is the best. However, if any variation is to be tolerated, it is better if the solder bumps in the chip site portion of the substrate define a more concave than convex profile at reflow. A concave profile provides stable support points at the corners of a chip whereas a convex profile can only support the chip at its geometric peak point with a potential to tip arbitrarily. Under tipped or tilted conditions, the z-gap on the up-lifted corner can cause C4s to become non-wet.

FIGS. 3a and 3b show the reflow warp along a diagonal (section-1) shown in FIG. 3c for two different substrate designs. Substrate A exhibits a concave shape while substrate B shows a convex profile at the 225° C. reflow temperature. The convex shape of the substrate in this exemplary embodiment is contained within a rectangle of height about 10 μm. The corresponding failure analysis for C4 non-contact/non-wet confirms the observation that a convex profile at reflow is not conducive to good C4 joining.

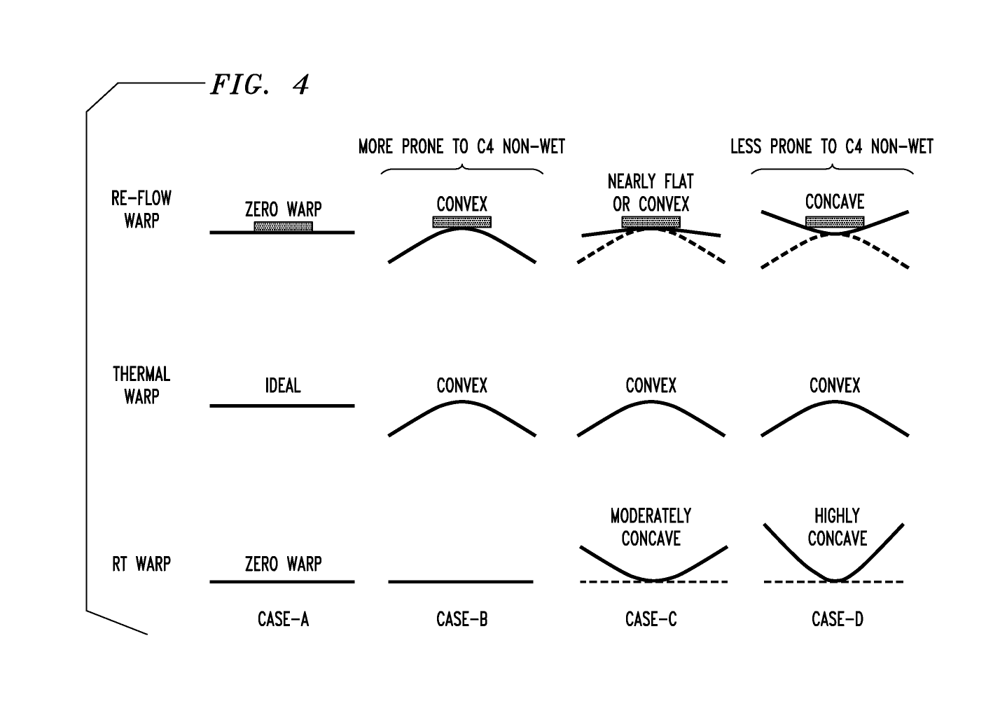

It is important to establish the thermomechanical process that contributes to a specific profile at reflow so that corrective action can either be taken to avoid this problem altogether or so it can be circumvented through the conformal coining process described herein. FIG. 4 schematically presents various possible warp conditions. FIG. 4, Case-A corresponds to an ideal situation where the substrate has a perfectly planar surface at room temperature and the thermal warp is nil. Therefore at reflow the substrate remains planar. Case-B corresponds to a non-zero thermal warp with a planar profile at room temperature (RT). The thermal warp component (absolute warp at reflow-absolute warp at RT) is typically convex in shape due to a higher CTE of the upper build-up layer. The RT profile is seldom found to be planar and therefore Case-B does not frequently occur in real situations. However, at reflow this produces a highly convex profile which is not conducive for generating a good C4 joint. Case-C is more close to reality where the concave RT profile is made more or less planar at the reflow temperature as the thermal warp component neutralizes the RT profile. (The convex and concave profiles in this figure are exaggerated for purposes of illustration.)

The physical phenomena generally evolves such that the reflow profile is generally planar and thermal warp due to cooling produces a concave profile at RT. Case-D corresponds highly concave RT profile leading to a clearly concave profile at reflow temperature. In summary, if the RT concave profile and convex-profiled thermal warp are identical then the reflow profile is likely to be planar. However, for reasons yet to be described, if the RT profile is mildly concave compared to the thermal (convex) profile, then the reflow profile is likely to be convex, thus producing poor conditions for C4 joining.

FIG. 5 shows a sequence of thermal warp components of substrate-B of FIG. 3b as the temperature of the substrate is changed from 25° C. to 225° C. and then brought hack to RT. The thermal cycle takes about 3 hours in this particular experiment. The substrate reaches a peak convex thermal component at 225° C., but as the temperature is reduced back to the RT (25° C.), the thermal component does not return to zero warp condition but has a concave shape. This effect is believed to be due to creep-relaxation of the dielectric contained within the upper build up layer of the substrate. A magnitude of 10 μm within the chip-site is observable. This component is related to the 10 μm high convex profile at reflow measured in the same substrate-B as shown in FIG. 3b. It is evident that creep enters into warp-mechanics of the organic substrate, and more attention needs to be paid to the creep effect if excellent reflow processing is to be achieved.

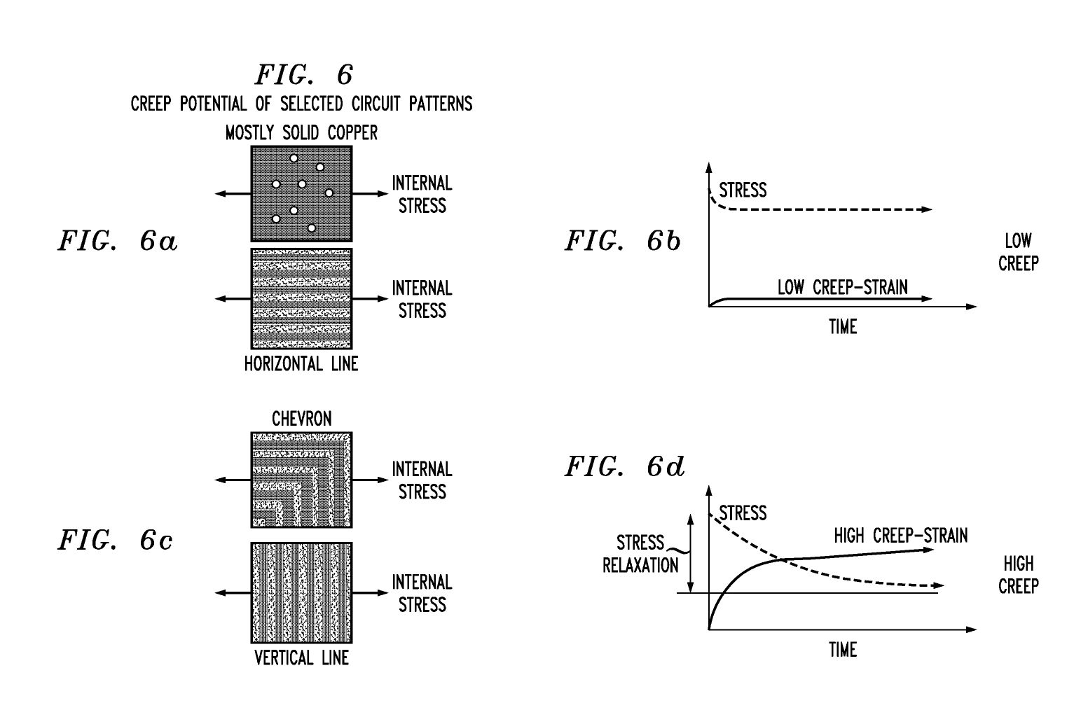

FIGS. 6a and 6b show two groups of typical build-up layers that may be found in a laminated substrate employed in an electronic package. It is understood that copper creeps at much slower rate compared to dielectric for a given applied stress. A resin-rich area is often present under the area where the silicon die is to be placed on the substrate. This is usually at the center of the substrate, which can be referred to as the chip site or flip chip attachment area (FCA). Outside the FCA the metallic layers are often mostly solid with minor cuts and contain proportionally less dielectric material. The exemplary embodiment of FIG. 6a has solid or horizontal lines structure in which copper takes the dominant stress and the resin (dielectric) is protected from direct stress. Hence the level of stress relaxation as a result of creep due to application of a tensile (or compressive stress) is not strong. However. FIG. 6b shows “chevron” or vertical lines transmit the same stress component to resin therefore resulting in a higher creep rate. Relaxation in chevron patterns is relatively high in both the x and y directions. Patterns comprised of parallel lines are vulnerable to creep relaxation in only one direction. Such observations can be applied to uncover the residual thermal warp observed in an organic substrate.

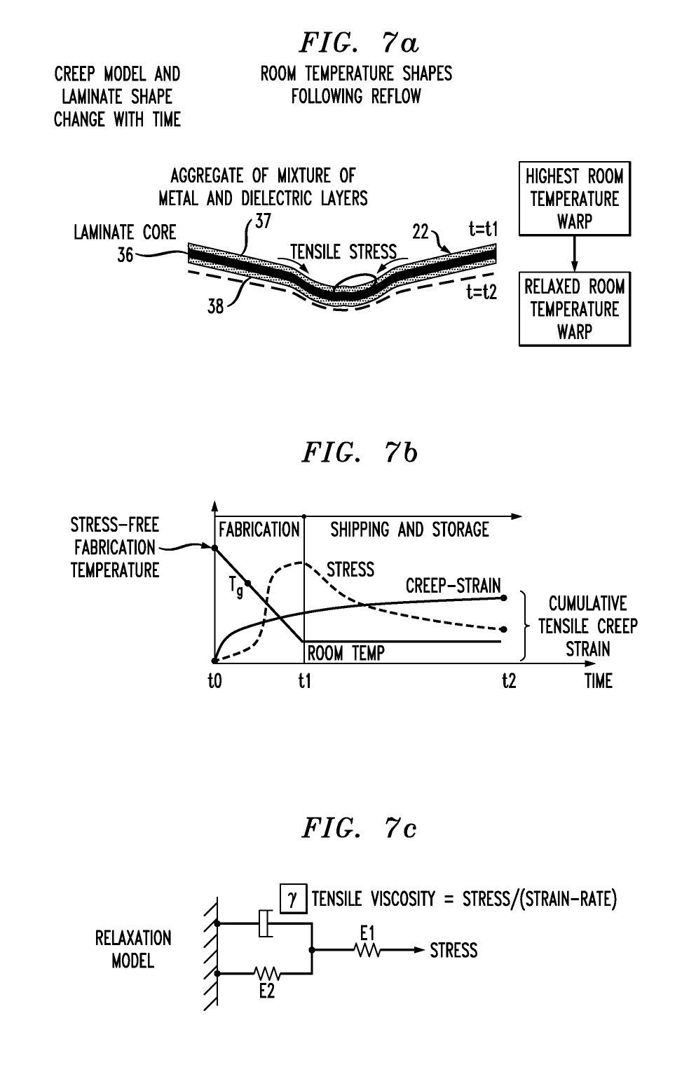

FIGS. 7a-c show the creep relaxation of creep sensitive layers found in substrate-B. The substrate in this exemplary embodiment is comprised of a polymer core 36 having a Young's modulus of about 20 GPa. The two outer layers 37, 38 represent an aggregate of metallic (e.g. copper) layers and dielectric material (polymer). At the end of fabrication (time=t₀) the substrates are at high temperature and are more or less planar and the dielectric is stress free. Since CTE of the top build-up layer 37 is usually high due to a higher volumetric content of resin, this layer tends to contract much more than the bottom build-up layer 38. The contraction produces not only warp of the core and the substrate 22 as shown in FIG. 7a but also generates internal tensile stresses leading to creep relaxation. Thus, as shown in FIG. 7b, the RT stress and warp at t=t1 are larger than that at t=t2. The relaxation at RT may take place over several days. FIG. 7c shows an equivalent “spring-damper” model to capture the elastic and creep strain components in the build-up layer.

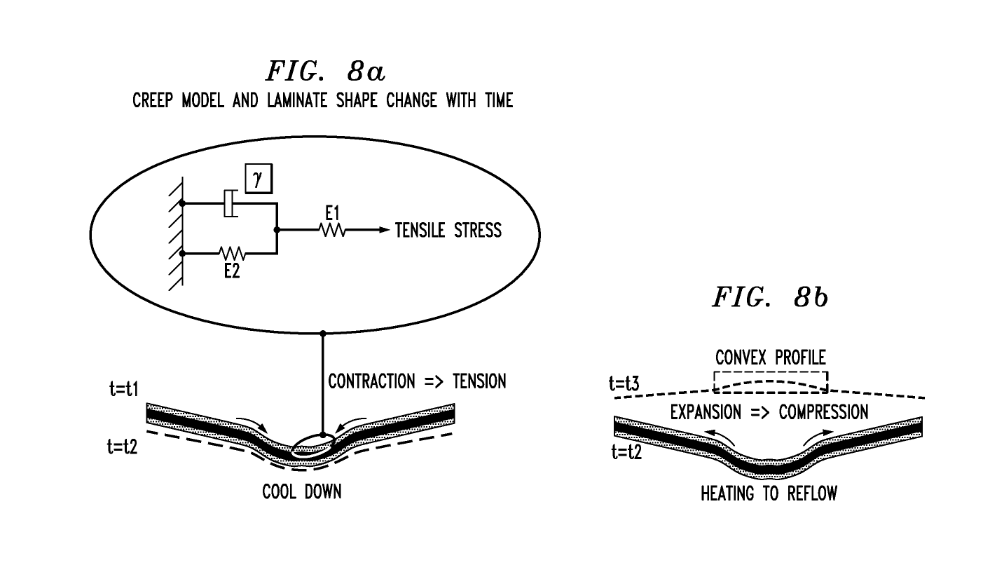

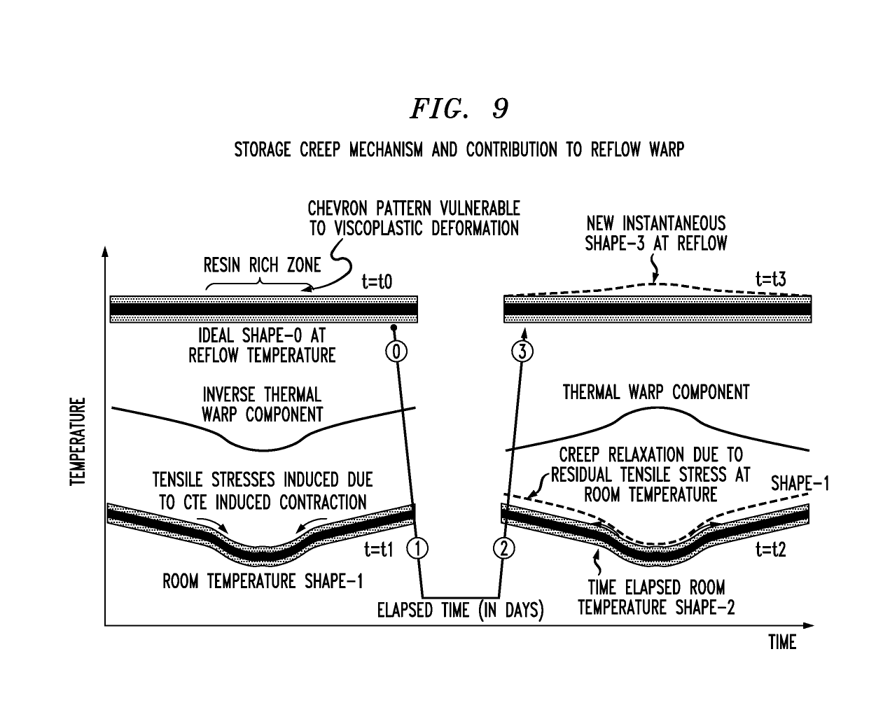

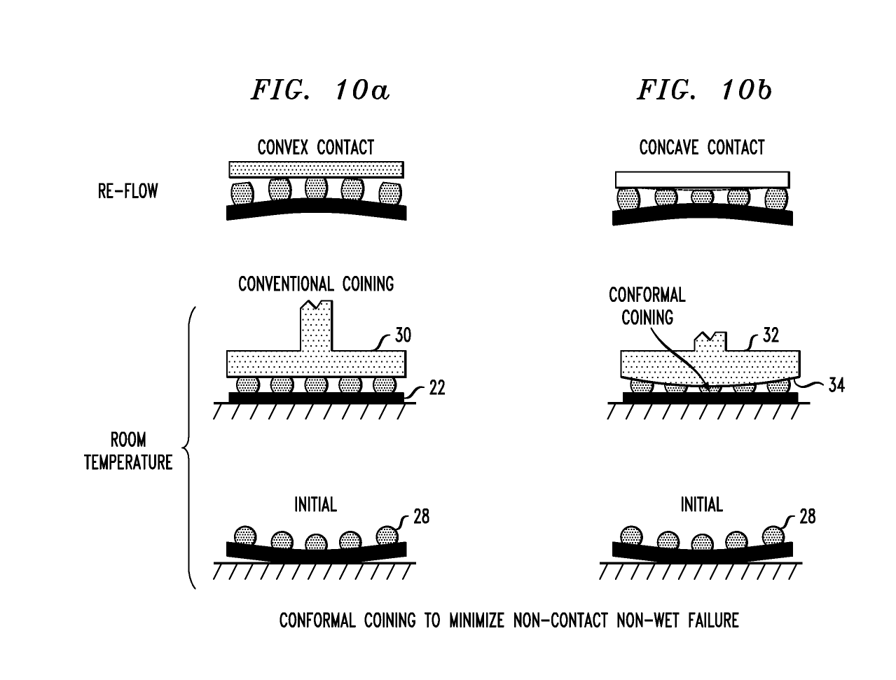

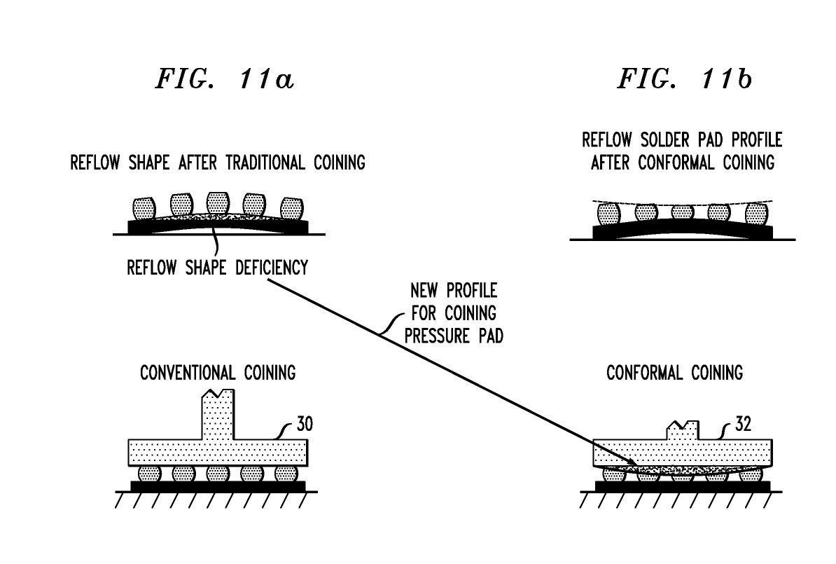

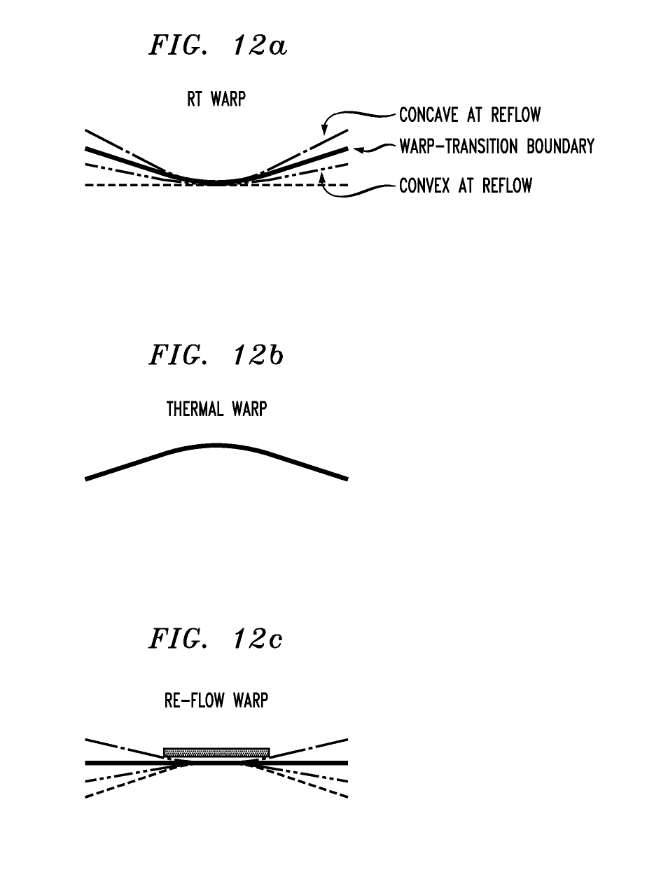

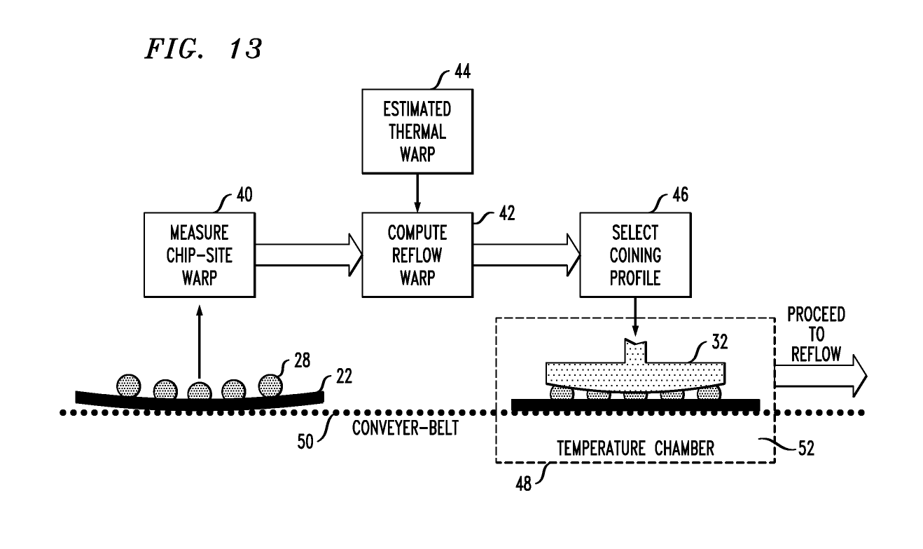

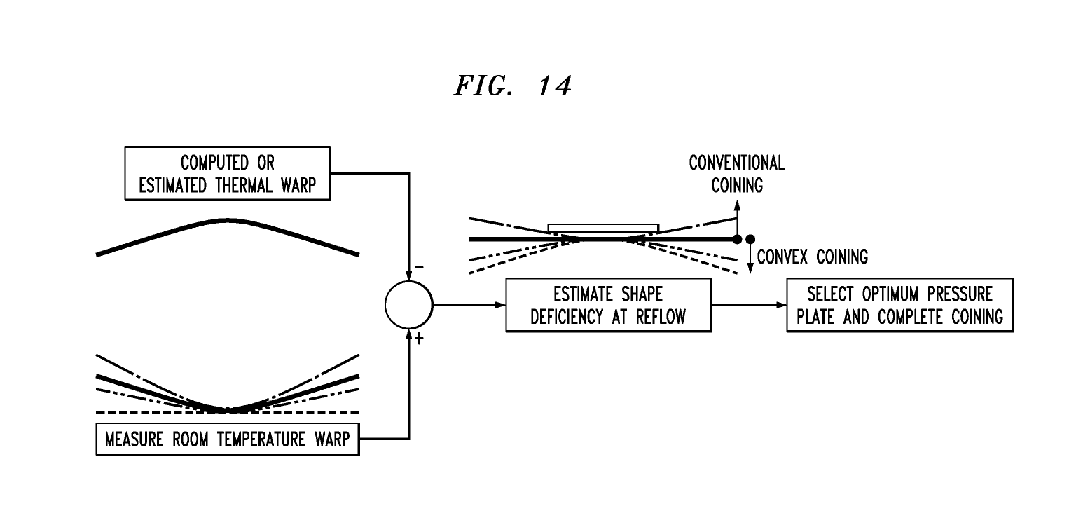

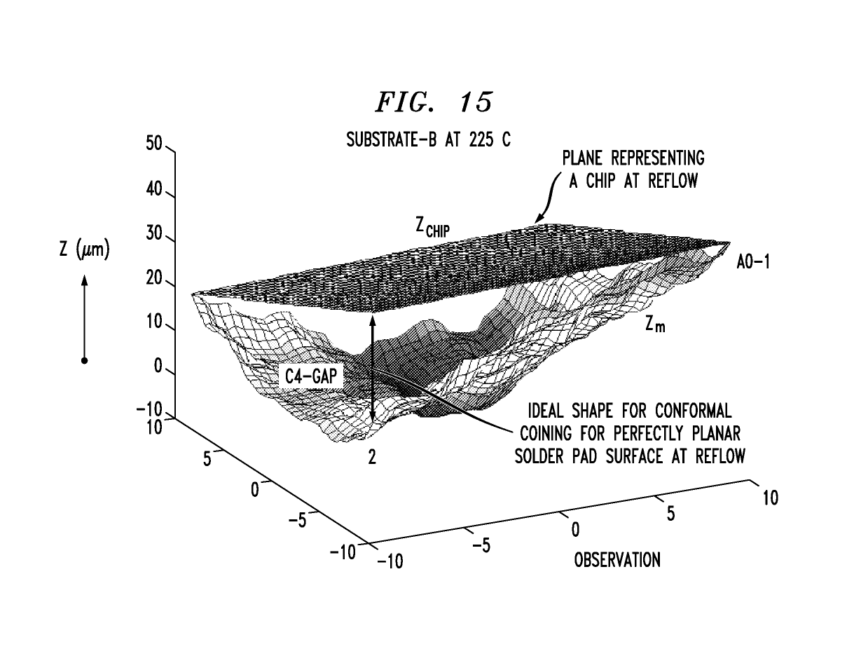

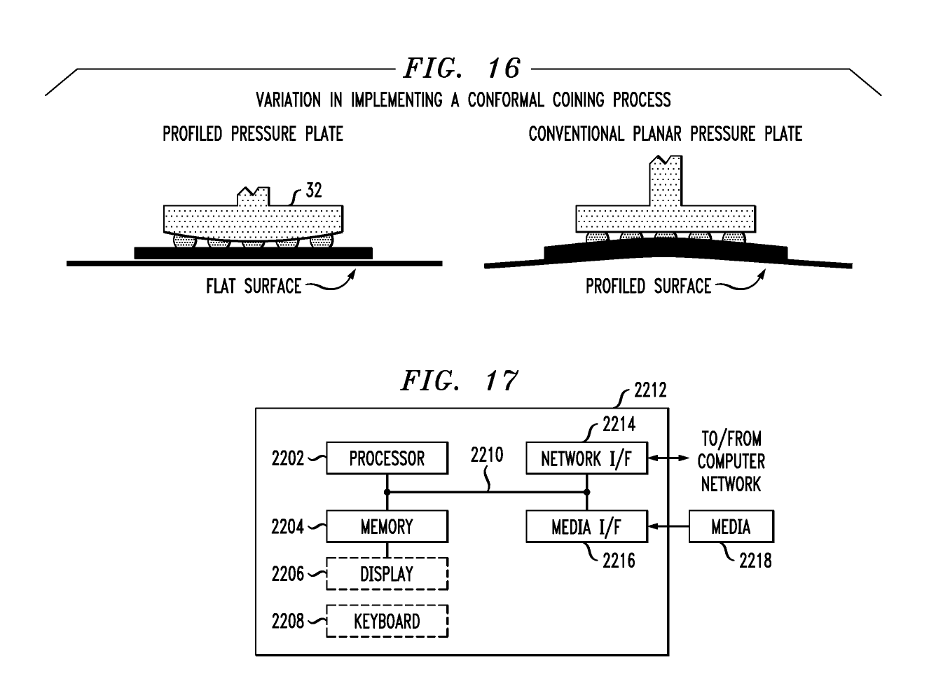

FIGS. 8a and 8b show the relaxation effect from cool clown to reflow heating. The creep-model discussed in FIG. 7c takes a tensile stress during cool down and compressive stress during the heating process. When the substrate is heated to reflow, well above the glass transition temperature (Tg) of the dielectric, compressive stress is generated and reverse creep effect takes place, but may not completely come to the original stress free state at reflow. The residual compressive stress can cause a convex profile at reflow (t=t3) detrimental to C4-joining.

FIG. 9 shows the first cool down and subsequent heating of a substrate (like substrate-B of FIG. 3) with built-up layers sensitive to creep. The illustration demonstrates that a) there is a substantial change in warp from RT to reflow defined as “thermal warp”, and b) there can be a time dependent warp component that may require consideration in defining the expected reflow profile given that the “thermal-warp” is already known. In addition to these two components, there can be a third component that can also contribute to z-deformation of the profile. For instance, the trapped resin between two circuit layers containing solid copper vias can “blister” through large openings found between adjacent circuit patterns, thus producing a direct change in reflow profile.

FIG. 10a shows a conventional coining process that does not take into account the RT temperature warp and temperature-induced change in warp. The bottom surface of the coining pressure plate 30 is planar and will cause the solder bumps 28 to form a planar surface. Therefore, at reflow a convex substrate and corresponding convex solder bump profile is possible. FIG. 10b shows an exemplary embodiment of the invention where the coining profile of the pressure plate 32 is configured to account for the expected change in shape from RT to reflow. In this embodiment, the surface 34 of the pressure plate that contacts the solder bumps is convex. Once the coining profile is applied to the solder on the pads, concave or planar C4 contact is probable.

FIG. 11a defines a fundamental profile needed to modify the coining pressure plate. The reflow shape deficiency defined in FIG. 11a is directly transferred to profile the pressure plate in FIG. 11b, or the shape is exaggerated by a margin (e.g. by 10% enlargement in z direction) so that, following coining, a concave solder surface profile is presented to the die having the C4 solder bumps. In reality, the thermal warp is not a fixed component but is statistically distributed. The thermal warp of two substrates including identical circuit design may not be identical. This difference occurs due to thickness variation of copper and dielectric layers observed following a fabrication process. For example, thickness variation of copper could occur due to non-uniform electroplating process. When multiple laminates (typically 8×10) are built on a large panel, the electrolyte in the central area tends to become more depleted than near the edges. Hence the thermal warp of a population of substrates will have a “mean” and a “standard deviation” corresponding to the statistical nature of the manufacturing process. It should be noted that the absolute warp (which is the sum of absolute warp at a reference temperature+thermal warp) at any given temperature for a population of laminates will have a “mean” and a “standard deviation” that is different from that of the thermal warp component. Under this definition the “standard deviation” of absolute warp is always greater than the corresponding thermal warp. The contact surface of the coining pressure plate can be given a fixed shape based on the “mean” thermal warp component of the substrate in the FCA. While the solder surface profile based on mean or average thermal warp may not be perfect, solder joining should be superior to conventional coining as the z-gaps will be substantially reduced compared to a conventional flat coining operation. If further fine tuning is necessary for certain applications, the actual warp at room temperature can also be taken into account when selecting the contact surface profile of a coining pressure plate.

FIG. 12 shows the RT profile which will have a nominal profile (i.e., mean value) with variations around it. Hence, for a “fixed profile” used in a coining process, some of the substrates can end up exhibiting a convex profile at reflow. Thus, at the simplest level, substrates having lower warp at RT can be sorted and excluded from the reflow process. There is a “warp-transition-boundary” as shown in FIG. 12 that can be used to sort out the substrates that have the potential to become convex or concave at reflow temperature.

The rejection of substrates due to a “fixed profile coining process” can be reduced or eliminated by an adaptive coining process. FIG. 13 shows a process flow where the chip-site warp of the substrate 22 is measured in real-time in step 40, thus accounting for creep relaxation as well as for process induced absolute warp variation, and fed to a computer which computes the expected reflow profile (warp) in step 42. The thermal warp is either measured from a population sample or estimated using a warp projection tool in step 44 and inputted to the computer. A typical warp measurement tool, such a digital image correlator (DIC) readily available in the commercial market, facilitates rapid and non-contact measurement of warp of a laminate. The output of a DIC tool is a three dimensional description of the warp surface. For example a DIC tool will provide a matrix of z-position values of a laminate for a selected set of (x,y) coordinates. The measured chip-site (or FCA) warp and/or the measured/estimated thermal warp components are stored in the memory prior to being input into a processor. The absolute measurement of warp at room temperature just prior to the reflow process eliminates the complexity of accounting for the creep effect. Past history of the laminate to account for creep is irrelevant in this case which is also the preferred form of implementing the conformal coining method. The desired reflow profile (for example, a 5 um deep concave paraboloid surface) coordinate information is also preselected and stored as a mathematical function (z=f(x,y)). The processor now computes the required coining profile to achieve the desired profile at reflow given that the initial warp at room temperature as well as the thermal warp components are already made available to the processor. The coining profile information just computed by the processor is sent to an adaptive coining machine. The adaptive coining machine may have the capability to dynamically alter the coining profile using a robotic profile generator. Similar to the function of a deformable mirror used in specialized telescopes, a miniature robotic profile generator that receives the (x,y,z) command from the processor configures the shape of the pressure plate. Since the pressure encountered by the pressure plate surface during the coining operation can be substantial, a gear system that is insensitive to backlash or reverse motion should be employed. Alternatively, such a machine may include an array of predefined, prefabricated pressure plates having different profiles to complete the “conformal coining” process. One of the pressure plates that most closely matches the (x,y,z) command from the processor will be chosen in accordance with instructions from the processor. A coining pressure plate profile is selected in step 46. Following such selection, the coining process is performed in step 48. In this exemplary embodiment, the solder bumps 28 are coined by the convex bottom surface of the pressure plate to provide a concave solder surface. The substrate then proceeds to reflow where C4 joining may be effected.

FIG. 14 traces the same steps outlined by FIG. 13 by means of illustrative profiles. As illustrated, conventional coining using a plate having a planar contact surface can be used if the substrate is expected to be concave or planar at reflow. If a convex substrate profile is expected at reflow, a convex contact surface profile is selected to form a concave solder surface. A conveyor belt 50 transports the substrates 22 during the above procedure.

Ultimately the success of a C4-joining may require exact reproduction of the z-gap at reflow. FIG. 15 shows the computation of the z-gap where the profile is mostly concave, yet it has the potential to miss the C4's in corner 2. By computing the three dimensional profile of large sample sizes, the “conformal coining” method can be further perfected. The measurement and computational sequence to address a generic reflow surface of a laminate such as shown in FIG. 15 is identical to the procedure that has been discussed above. Measurement of absolute warp at room temperature for each laminate removes many uncertainties that encroach into the estimation of reflow warp.

The coining process can be improved by performing the operation at higher than room temperature, preferably around 75° C. or above. At higher temperature the solder creeps more easily and the substrate 22 becomes planar against the supporting bottom surface. Coining can accordingly be performed in a temperature chamber 52 as shown in FIG. 13.

In an alternative embodiment shown in FIG. 16, the bottom surface can be profiled to obtain a suitable solder surface profile without the uncertainty of substrate deformation under coining pressure. Since the substrate has a deformed shape at room temperature it is likely remain partially deformed even when a coining pressure is applied to it on the top surface thus not guaranteeing a perfectly flat reference plane. The bottom surface of the substrate may remain separated from the supporting plane thus producing some uncertainty in its deformed position. The substrate in this embodiment, as shown on the right hand side of the drawing, is placed on a convex support surface and the solder bumps thereon are compressed by a coining pressure plate having a planar contact surface. The solder bumps will accordingly define a concave surface similar to the surface formed by the coining process shown on the left side that employs a coining pressure plate having a convex surface.

The substrate profile may alternatively used to coin the die having the C4s. Thus far the focus to achieve desirable reflow has been to leverage the solder bumps available on the substrate. However, the silicon die also has solder based C4s that can be used for conformal coining. However to avoid excessive stress on devices (eg, transistors) contained below the C4s on the die, higher temperatures can be employed for conformal coining. If the C4s are coined rather than the solder bumps on the substrate, they would preferably define a concave surface to match the planar or convex surface defined by the solder bumps on the substrate at reflow.

Given the discussion thus far, it will be appreciated that, in general terms, an exemplary method, according to an aspect of the invention, includes the steps of providing an organic substrate including a plurality of solder bumps and, obtaining an expected profile of the organic substrate at reflow. As discussed above, the expected profile can be obtained through knowledge of thermal deformation information relating to the substrate. Room temperature warp information can be employed in addition to the thermal deformation information in obtaining the expected profile of the organic substrate at reflow. The expected profile can be a mean value based on a population of similar substrates. The method further includes selecting a contact surface profile for a coining pressure plate based on the expected profile of the organic substrate and deforming the solder bumps by applying pressure to the solder bumps with the contact surface of the coining pressure plate to form a substrate solder surface having a profile corresponding to the contact surface profile of the coining pressure plate. It will be appreciated that if the contact surface of the coining pressure plate is convex, the solder surface profile of the organic substrate will be concave.

In accordance with a further aspect of the invention, a method includes providing an organic substrate including a chip site comprising a plurality of first solder bumps and a die including a plurality of second solder bumps arranged for forming solder joints with the first solder bumps. An expected profile of the chip site of the organic substrate at reflow is obtained. Based on the expected profile, a desired solder surface profile for one of the pluralities of first and second solder bumps is determined. The desired solder surface profile is provided on one of the pluralities of first and second solder bumps by applying pressure to the one of the pluralities of first and second solder bumps with a coining plate. The coining plate may include a contact surface that is selected for deforming the solder bumps to the desired profile such as shown in the exemplary embodiment of FIG. 10b. Alternatively, the support surface for the organic substrate can be profiled as shown in the exemplary embodiment of FIG. 16 and a planar coining plate employed to deform the solder bumps.

In accordance with another aspect, a method is provided that comprises determining whether an expected profile of a chip site on an organic substrate comprising solder bumps is convex at a reflow temperature of the solder bumps, and coining the solder bumps with a coining pressure plate having a convex surface if the expected profile of the chip site is convex. FIG. 4 schematically illustrates various possible profiles of substrates that may be encountered. In cases where a substrate is relatively prone to C4 non-wetting, a coining pressure plate such as that shown in FIG. 10b can be employed. In cases less prone to C4 non-wetting, a planar coining plate can be used to deform the solder bumps.

### Exemplary System and Article of Manufacture Details

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

A computer program product for selecting a coining profile for an organic substrate including a plurality of solder bumps on the substrate is provided in accordance with a further aspect of the invention. The computer program product comprises a computer readable storage medium having computer readable program code embodied therewith, the computer readable program code comprising computer readable program code containing program instructions, wherein execution of the instructions by one or more processors causes the one or more processors to carry out the steps of obtaining thermal warp information relating to the profile of an organic substrate including a plurality of solder bumps at a reflow temperature of the solder bumps, determining an expected profile of the organic substrate at reflow from the thermal warp information, and sending information relating to a coining profile to be chosen for the organic substrate based on the expected profile. The coining profile information can be sent, for example, to an adaptive coining machine as described above.

One or more embodiments of the invention, or elements thereof, can be implemented in the form of an apparatus including a memory and at least one processor that is coupled to the memory and operative to perform exemplary method steps such as those illustrated in FIGS. 13 and 14. Specifically, computer readable program code containing program instructions can be provided, wherein execution of the instructions by one or more processors causes the one or more processors to carry out the steps of obtaining thermal warp information relating to the profile of at least one portion of an organic substrate including a plurality of solder bumps at a reflow temperature of the solder bumps, obtaining creep relaxation information relating to the profile of the at least one portion of the organic substrate, determining the expected profile of the at least one portion of the organic substrate at reflow, and sending information relating to a coining profile to be chosen for the organic substrate. As discussed with respect to FIGS. 13 and 14, the information relating to the coining profile can be sent to an adaptive coining machine that uses such information to provide a coining pressure plate having the appropriate profile for shaping the substrate solder surface.

One or more embodiments can make use of software running on a general purpose computer or workstation. With reference to FIG. 17 such an implementation might employ, for example, a processor 2202, a memory 2204, and an input/output interface formed, for example, by a display 2206 and a keyboard 2208. The term “processor” as used herein is intended to include any processing device, such as, for example, one that includes a CPU (central processing unit) and/or other forms of processing circuitry. Further, the term “processor” may refer to more than one individual processor. The term “memory” is intended to include memory associated with a processor or CPU, such as, for example, RAM (random access memory), ROM (read only memory), a fixed memory device (for example, hard drive), a removable memory device (for example, diskette), a flash memory and the like. In addition, the phrase “input/output interface” as used herein, is intended to include, for example, one or more mechanisms for inputting data to the processing unit (for example, mouse), and one or more mechanisms for providing results associated with the processing unit (for example, printer). The processor 2202, memory 2204, and input/output interface such as display 2206 and keyboard 2208 can be interconnected, for example, via bus 2210 as part of a data processing unit 2212. Suitable interconnections, for example via bus 2210, can also be provided to a network interface 2214, such as a network card, which can be provided to interface with a computer network, and to a media interface 2216, such as a diskette or CD-ROM drive, which can be provided to interface with media 2218.

Accordingly, computer software including instructions or code for performing the methodologies of the invention, as described herein, may be stored in one or more of the associated memory devices (for example, ROM, fixed or removable memory) and, when ready to be utilized, loaded in part or in whole (for example, into RAM) and implemented by a CPU. Such software could include, but is not limited to, firmware, resident software, microcode, and the like.

A data processing system suitable for storing and/or executing program code will include at least one processor 2202 coupled directly or indirectly to memory elements 2204 through a system bus 2210. The memory elements can include local memory employed during actual implementation of the program code, bulk storage, and cache memories which provide temporary storage of at least some program code in order to reduce the number of times code must be retrieved from bulk storage during implementation.

Input/output or I/O devices (including but not limited to keyboards 2208, displays 2206, pointing devices, and the like) can be coupled to the system either directly (such as via bus 2210) or through intervening I/O controllers (omitted for clarity).

Network adapters such as network interface 2214 may also be coupled to the system to enable the data processing system to become coupled to other data processing systems or remote printers or storage devices through intervening private or public networks. Modems, cable modem and Ethernet cards are just a few of the currently available types of network adapters.

As used herein, including the claims, a “server” includes a physical data processing system (for example, system 2212 as shown in FIG. 16) running a server program. It will be understood that such a physical server may or may not include a display and keyboard.

As noted, aspects of the present invention may take the form of a computer program product embodied in one or more computer readable medium(s) having computer readable program code embodied thereon. Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. Media block 2218 is a non-limiting example. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described herein with reference to flowchart illustrations and/or block diagrams of methods, apparatus (systems) and computer program products according to embodiments of the invention. It will be understood that certain blocks of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions winch execute on the computer or other programmable apparatus provide processes for implementing the functions/acts specified in the flowchart and/or block diagram block or blocks.

The flowchart and block diagrams in FIGS. 13 and 16 illustrate the architecture, functionality, and operation of possible implementations of systems, methods and computer program products according to various embodiments of the present invention. In this regard, blocks in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

It should be noted that any of the methods described herein can include an additional step of providing a system comprising distinct software modules embodied on a computer readable storage medium; the modules can include, for example, any or all of the elements depicted in the block diagrams and/or described herein. For example, a database module could be provided to store expected profiles of an organic substrate at reflow; a coining profile module could be provided to control selection of a coining profile based on expected profile information, and one or more modules may be provided for facilitating operation of a digital image correlator (DIC) and/or other warp measurement tools or warp projection models. The method steps can then be carried out using the distinct software modules and/or sub-modules of the system, as described above, executing on one or more hardware processors 2202. Further, a computer program product can include a computer-readable storage medium with code adapted to be implemented to carry out one or more method steps described herein, including the provision of the system with the distinct software modules In any case, it should be understood that the components illustrated herein may be implemented in various forms of hardware, software, or combinations thereof; for example, application specific integrated circuit(s) (ASICS), functional circuitry, one or more appropriately programmed general purpose digital computers with associated memory, and the like. Given the teachings of the invention provided herein, one of ordinary skill in the related art will be able to contemplate other implementations of the components of the invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising.” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A method comprising:
providing an organic substrate including a plurality of solder bumps;
obtaining an expected profile of the organic substrate at reflow;
selecting a contact surface profile for a contact surface of a coining pressure plate based on the expected profile of the organic substrate, and
deforming the solder bumps by applying pressure to the solder bumps with the contact surface of the coining pressure plate, thereby forming a substrate solder surface having a profile corresponding to the contact surface profile of the coining pressure plate.

2. The method of claim 1, wherein the contact surface of the coining pressure plate is convex and the step of deforming the solder bumps produces a concave solder surface profile on the organic substrate.

3. The method of claim 1, wherein the step of obtaining the expected profile of the organic substrate at reflow includes obtaining thermal warp information relating to the profile of the organic substrate at a reflow temperature of the solder bumps and determining the expected profile of the organic substrate from the thermal warp information.

4. The method of claim 3, wherein the step of obtaining the expected profile of the organic substrate at reflow further includes obtaining room temperature warp information relating to the organic substrate and determining the expected profile of the organic substrate from the room temperature warp information.

5. The method of claim 1, further including the steps of contacting the substrate solder surface with a solder surface of a die comprising an integrated circuit and joining the substrate and the die by reflowing the solder surfaces.

6. The method of claim 1, wherein the step of selecting the contact surface profile includes selecting a coining pressure plate having the conformal contact surface profile from an array of coining pressure plates having predefined contact surface profiles.

7. The method of claim 1, wherein the step of selecting the contact surface profile includes altering the profile of a coining pressure plate.

8. The method of claim 1 wherein the expected profile is the expected profile of a chip site on the organic substrate.

9. A method comprising:
providing an organic substrate including a chip site comprising a plurality of first solder bumps;
providing a die including a plurality of second solder bumps arranged for forming solder joints with the first solder bumps;
obtaining an expected profile of the chip site of the organic substrate at reflow;
determining a desired solder surface profile for one of the pluralities of first and second solder bumps based on the expected profile of the chip site of the organic substrate at reflow, and
providing the desired solder surface profile on the one of the pluralities of first and second solder bumps by applying pressure to the one of the pluralities of first and second solder bumps with a coining plate.

10. The method of claim 9, wherein the desired solder surface profile is concave.

11. The method of claim 9, further comprising positioning, the organic substrate on a convex support surface and applying pressure to the first solder bumps with the coining plate to provide the desired solder surface profile.

12. The method of claim 9, wherein the step of obtaining the expected profile of the chip site of the organic substrate at reflow further comprises obtaining thermal warp information relating to the profile of the chip site of the organic substrate at reflow and determining the expected profile from the thermal warp information.

13. The method of claim 12, wherein the step of obtaining the expected profile of the chip site of the organic substrate at reflow further comprises obtaining room temperature warp information relating to the chip site of the organic substrate and determining the expected profile from the room temperature warp information.

14. The method of claim 9, further including selecting a contact surface profile for a contact surface of the coining plate based on the expected profile of the chip site of the organic substrate at reflow.

15. The method of claim 14, wherein the step of providing the desired surface profile includes engaging the plurality of first solder bumps with the contact surface of the coining plate.

16. The method of claim 15 wherein the step of obtaining the expected profile of the chip site of the organic substrate at reflow further comprises obtaining thermal warp information relating to the profile of the chip site of the organic substrate at reflow and determining the expected profile from the thermal warp information.

17. A method comprising:
determining whether an expected profile of a chip site on an organic substrate comprising solder bumps is convex at a reflow temperature of the solder bumps, and
coining the solder bumps with a coining pressure plate having a convex surface if the expected profile of the chip site is convex.

18. The method of claim 17, wherein the step of determining whether the expected profile is convex further includes obtaining thermal warp information relating to the profile of the chip site at the reflow temperature of the solder bumps.

19. The method of claim 18, wherein the step of determining whether the expected profile is convex further includes obtaining room temperature warp information relating to the chip site of the organic substrate and determining the expected profile from the room temperature warp information.

20. The method of claim 17, further including the step of selecting a contact surface for the coining pressure plate based on a mean thermal warp of chip sites on a plurality of organic substrates.

21. The method of claim 17, further including the steps of:
obtaining thermal warp information relating to the profile of the chip site at the reflow temperature of the solder bumps;
obtaining room temperature warp information relating to the profile of the chip site of the organic substrate;
obtaining a desired solder surface profile for the solder bumps at reflow, and
selecting a contact surface for the coining pressure plate based on the thermal warp information, the room temperature warp information, and the desired solder surface profile at reflow.

22. A computer program product for selecting a coining profile for an organic substrate including a plurality of solder bumps on the substrate, said computer program product comprising:
a computer readable storage medium having computer readable program code embodied therewith, said computer readable program code comprising:
computer readable program code containing program instructions, wherein execution of the instructions by one or more processors causes the one or more processors to carry out the steps of:
obtaining thermal warp information relating to the profile of an organic substrate including a plurality of solder bumps at a reflow temperature of the solder bumps;
determining an expected profile of the organic substrate at reflow from the thermal warp information, and
sending information relating to a coining profile to be chosen for the organic substrate based on the expected profile.

23. The computer program product of claim 22, wherein execution of the instructions by one or more processors causes the one or more processors to further carry out the step of obtaining creep relaxation information relating to the profile of the organic substrate and the step of determining the expected profile of the organic substrate at reflow further includes using the creep relaxation information.

24. The computer program product of claim 23 wherein the thermal warp information relates to a chip site on the organic substrate.

25. The computer program product of claim 24 wherein the step of obtaining creep relaxation information is conducted at room temperature.
